(19) United States
(12) Patent Application Publication
(10) Pub. No.: US 2009/0001373 A1
(43) Pub. Date: Jan. 1, 2009

(54) ELECTRODE OF ALUMINUM-ALLOY FILM WITH LOW CONTACT RESISTANCE, METHOD FOR PRODUCTION THEREOF, AND DISPLAY UNIT

(75) Inventors: Mototaka OCHI, Kobe-shi (JP); Hiroshi Gotou, Kobe-shi (JP); Hiroyuki Okuno, Kobe-shi (JP); Yuichi Taketomi, Kobe-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Kobe Seiko Sho (Kobe Steel Ltd.), Kobe-shi (JP)

(21) Appl. No.: 12/136,409

(22) Filed: Jun. 10, 2008

(30) Foreign Application Priority Data
Jun. 26, 2007 (JP) 2007-168295

(51) Int. Cl. H01L 29/04; H01L 21/28

(52) U.S. Cl. 257/59; 438/585; 257/E21.177; 257/E29.003

(57) ABSTRACT

Disclosed herein are an electrode of aluminum alloy film, a method for production thereof, and a display unit provided therewith, said electrode exhibiting a low electric resistance when in contact with a transparent oxide conductive film even though the aluminum alloy contains a less amount of alloying element than usual. The electrode of low contact resistance type is an aluminum alloy film in direct contact with a transparent oxide electrode, wherein said aluminum alloy film contains 0.1-1.0 atom % of metal nobler than aluminum and is in direct contact with a transparent oxide electrode through a surface having surface roughness no smaller than 5 nm in terms of maximum height Rz.

### BACKGROUND OF THE INVENTION

1. Field of the Invention

The present invention relates to an electrode of aluminum-alloy film, a method for production thereof, and a display unit provided therewith, the electrode having a low contact resistance and finding use in flat electronic display units typified by liquid crystal display units.

2. Description of the Related Art

Liquid crystal display units find use in broad applications ranging from small portable telephones to large televisions exceeding 30 inches. They fall under two classes—simple matrix type and active matrix type—according to the pixel driving method. The latter employs thin film transistors (TFT) as switching elements and is in general use because of its ability to produce high-quality images.

FIG. 1 is a schematic enlarged sectional view showing the structure of a typical liquid crystal panel used for the liquid crystal display unit of active matrix type. The shown liquid crystal panel is composed of a TFT array substrate 1, a facing substrate 2 (which faces the TFT array substrate), and a liquid crystal layer 3 which is interposed between the TFT substrate 1 and the facing substrate 2 and functions as an optical modulating layer. The TFT array substrate 1 is composed of an insulating glass substrate 1a, thin film transistors (TFTs) 4, wirings 6, and a light shielding film 9 opposite to the wirings 6.

The insulating substrates for the TFT substrate 1 and the facing substrate 2 are lined respectively with polarizers 10 and 10. In addition, the facing substrate 2 has an alignment layer 11 to orient liquid crystal molecules contained in the liquid crystal layer 3.

The liquid crystal panel of the foregoing structure works in such a way that the facing substrate 2 and the transparent conductive film 5 generate an electric field between them which controls the direction of orientation of the liquid crystal molecules in the liquid crystal layer 3. With their orientation controlled, the liquid crystal molecules modulate light passing through the liquid crystal layer 3 placed between the TFT array substrate 1 and the facing substrate 2. This results in a controlled passage of light through the facing substrate to generate images.

The TFT array is driven by the driver circuit 13 and the control circuit 14 through the TAB tape 12 led out of the TFT array. Incidentally, FIG. 1 also shows a spacer 15, a sealing material 16, a protective film 17, a diffusion film 18, a prism sheet 19, a light guide plate 20, a reflector 21, a back light 22, a supporting frame 23, and a printed circuit board 24.

FIG. 2 is a schematic sectional view illustrating the structure of the thin film transistor (TFT) applied to the array substrate for the display unit mentioned above. As shown in FIG. 2, the TFT has a glass substrate 1a and a scanning line 25 of aluminum-alloy thin film formed thereon. Part of the scanning line 25 functions as the gate electrode 26 to control on-off of the TFT. The TFT also has a signal line of aluminum thin film which intersects the scanning line 25 through the gate insulating film 27. Part of the signal line functions as the source electrode 28 of the TFT. Incidentally, this type is called the bottom gate type.

In the pixel region on the gate insulating film 27 is the transparent conductive film 5 (which is an ITO film composed of In₂O₃ and SnO). The drain electrode 29 of the thin film transistor (which is formed from aluminum-alloy film) is in direct contact with the transparent conductive film 5 for electrical connection.

When the gate electrode 26 is supplied with a gate voltage through the scanning line 25 on the TFT substrate 1a, the thin film transistor becomes on and the drive voltage (which has previously been applied to the signal line) is supplied to the transparent conductive film 5 from the source electrode 28 through the drain electrode 29. When a drive voltage of certain level is supplied to the transparent conductive film 5, a drive voltage is applied to the liquid crystal element between the facing common electrodes, so that the liquid crystal begins to work. Incidentally, FIG. 1 shows the structure in which the source-drain electrodes are in direct contact with the transparent conductive film. However, this structure may be modified such that the gate electrode (at its terminal) is in contact with the transparent conductive film 5 for electrical connection.

The signal line (wiring) for electrical connection to the transparent conductive film is formed from pure aluminum or aluminum alloy such as Al—Nd. It is also common practice to avoid direct contact with the transparent conductive film by interposing a barrier metal layer, which is a laminate layer composed of high-melting point metals such as Mo, Cr, Ti, and W. However, attempts are being made to make the signal line come into direct contact with the transparent conductive film without the high-melting point metals.

One of these new technologies is disclosed in Patent Document 1, which claims that direct contact with the signal line can be accomplished by using an oxide transparent conductive film of IZO composed of indium oxide and zinc oxide (10 mass %).

It is shown that direct contact with the transparent conductive film can be accomplished at a low electric resistance without the high-melting point metals if the drain electrode undergoes surface treatment such as plasma treatment or ion implantation (as disclosed in Patent Document 2) or if the gate, source, and drain electrodes are laminated with a second layer containing an impurity such as N, O, and Si (as disclosed in Patent Document 3).

The present inventors have been studying wiring film to be used for the thin electronic display unit mentioned above. The wiring film is formed from an aluminum alloy (such as Al—Ni) instead of pure aluminum so that it exhibits good conductivity and good heat resistance unrealizable with pure aluminum. As the result of their study, it was found that the electrode for electrical wiring is realized if an aluminum alloy is brought into direct contact with the visible light transparent oxide conductive film. They filed this idea for patent application (Patent Document 4). This application discloses a method for connecting an aluminum alloy film to the transparent pixel electrode directly and surely in a simple manner without additional steps. This method does not need a high-melting point metal layer which had been necessary for electrical connection between pure aluminum and a visible light transparent oxide conductive film.

### Patent Document 1:

Japanese Patent Laid-open No. Hei-11-337976

### Patent Document 2:

Japanese Patent Laid-open No. Hei-11-283934

### Patent Document 3:

Japanese Patent Laid-open No. Hei-11-284195

### Patent Document 4:

Japanese Patent Laid-open No. 2004-214606

### OBJECT AND SUMMARY OF THE INVENTION

Liquid crystal panels that have recently become larger than before pose a problem with uneven image display due to resistance of wiring between the gate electrode and the source-drain electrodes and ensuing delay in voltage pulse propagation. Therefore, a resistance as low as pure aluminum is required for wiring between the gate electrode and the source-drain electrodes that transmit signals in the display unit.

For the gate electrode and source-drain electrodes to have as low a wiring resistance as pure aluminum, the content of alloying elements in the aluminum alloy should be as small as possible. However, the results of the present inventors' investigation revealed that reduction of Ni content in Al—Ni alloys increases their contact resistance with the visible light transparent conductive film. The gate electrode and the source-drain electrodes of high contact resistance with the visible light transparent conductive film cause a trouble of defective display (defective glowing) in the display unit.

The present invention was completed in view of the foregoing. It is an object of the present invention to provide an electrode of aluminum alloy film, a method for production thereof, and a display unit provided therewith, the electrode exhibiting a low contact resistance with a transparent oxide conductive film even though the aluminum alloy contains a less amount of alloying element than usual.

The above-mentioned object of the present invention is achieved by an electrode of low contact resistance type which is an aluminum alloy film in direct contact with a transparent oxide electrode, wherein the aluminum alloy film contains 0.1-1.0 atom % of metal nobler than aluminum and is in direct contact with a transparent oxide electrode through a surface having surface roughness no smaller than 5 nm in terms of maximum height Rz. Incidentally, the maximum high roughness Rz accords with JIS B0601 (revised in 2001).

In the electrode of low contact resistance type according to the present invention, the metal nobler than aluminum is at least one species selected from the group consisting of Ni, Co, Ag, Au, and Zn, and the surface roughness are formed as an intermetallic compound containing such metals precipitates on the surface of the aluminum alloy film.

The foregoing aluminum alloy film may contain 0.1-0.5 atom % of at least one species of rare earth elements.

The electrode of low contact resistance type according to the present invention is suitable for use as the gate electrode and the source-drain electrodes. It will contribute to high-performance display units free of pixel errors.

The electrode of low contact resistance type mentioned above is produced by etching the surface of the aluminum alloy film with an alkaline solution, thereby forming the surface roughness mentioned above, before it is brought into direct contact with the transparent oxide conductive film. Etching should preferably be carried out such that the etching depth Rz is no smaller than 5 nm.

The electrode of low contact resistance type mentioned above is produced also by dry-etching the surface of the aluminum alloy film with a mixed gas of SF₆ and Ar before it is brought into direct contact with the transparent oxide conductive film.

### EFFECT OF THE INVENTION

According to the present invention, the aluminum alloy film is given surface roughness by wet etching with an alkaline solution or dry etching with a mixed gas of SF₆ and Ar, so that the alloying element precipitates on its surface. The result is a reduced contact resistance despite a small amount of alloying element, and this minimizes the number of pixel errors in the display unit.

### BRIEF DESCRIPTION OF THE DRAWINGS

FIG. 1 is a schematic enlarged sectional view showing the structure of a typical liquid crystal panel used for the liquid crystal display unit of active matrix type.

FIG. 2 is a schematic sectional view illustrating the structure of the thin film transistor (TFT) applied to the array substrate for the display unit.

FIG. 3 is a schematic diagram illustrating each step in sequential order for production of the array substrate for the display device shown in FIG. 2.

FIG. 4 is a schematic diagram illustrating each step in sequential order for production of the array substrate for the display device shown in FIG. 2.

FIG. 5 is a schematic diagram illustrating each step in sequential order for production of the array substrate for the display device shown in FIG. 2.

FIG. 6 is a schematic diagram illustrating each step in sequential order for production of the array substrate for the display device shown in FIG. 2.

FIG. 7 is a schematic diagram illustrating each step in sequential order for production of the array substrate for the display device shown in FIG. 2.

FIG. 8 is a schematic diagram illustrating each step in sequential order for production of the array substrate for the display device shown in FIG. 2.

FIG. 9 is a schematic diagram illustrating each step in sequential order for production of the array substrate for the display device shown in FIG. 2.

FIG. 10 is a schematic diagram illustrating each step in sequential order for production of the array substrate for the display device shown in FIG. 2.

FIG. 11 is a TEM photograph showing the cross section of the interface between the aluminum alloy thin film and the ITO film in Test No. 10 (according to the present invention).

FIG. 12 is a TEM photograph showing the cross section of the interface between the aluminum alloy thin film and the ITO film in Test No. 1 (for comparison).

FIG. 13 is a graph showing the relation between the surface roughness Rz of the aluminum alloy thin film and the contact resistance.

FIG. 14 is a TEM photograph showing the cross section of the interface between the aluminum alloy thin film and the ITO film in Test No. 44 (according to the present invention).

FIG. 15 is a TEM photograph showing the cross section of the interface between the aluminum alloy thin film and the ITO film in Test No. 35 (for comparison).

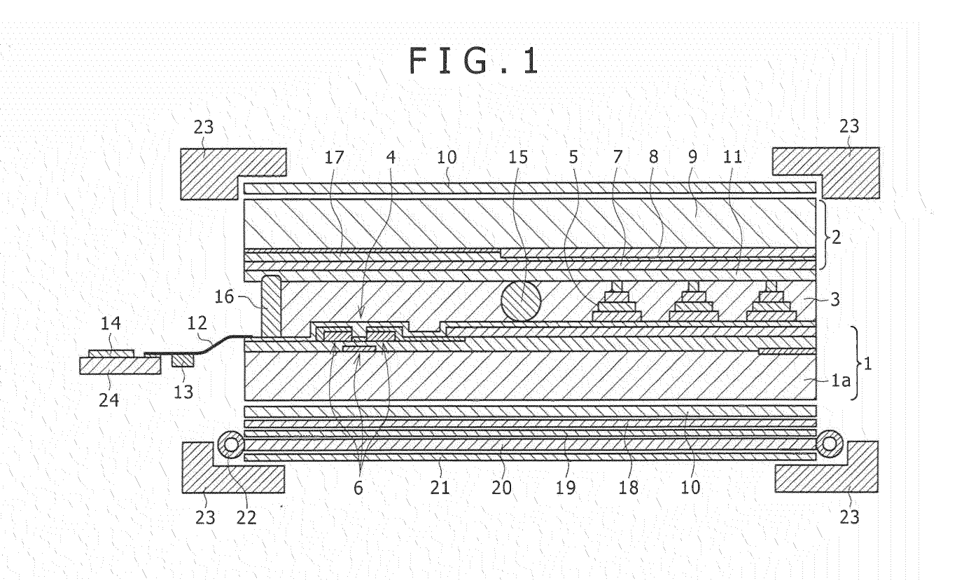

### DESCRIPTION OF THE PREFERRED EMBODIMENTS

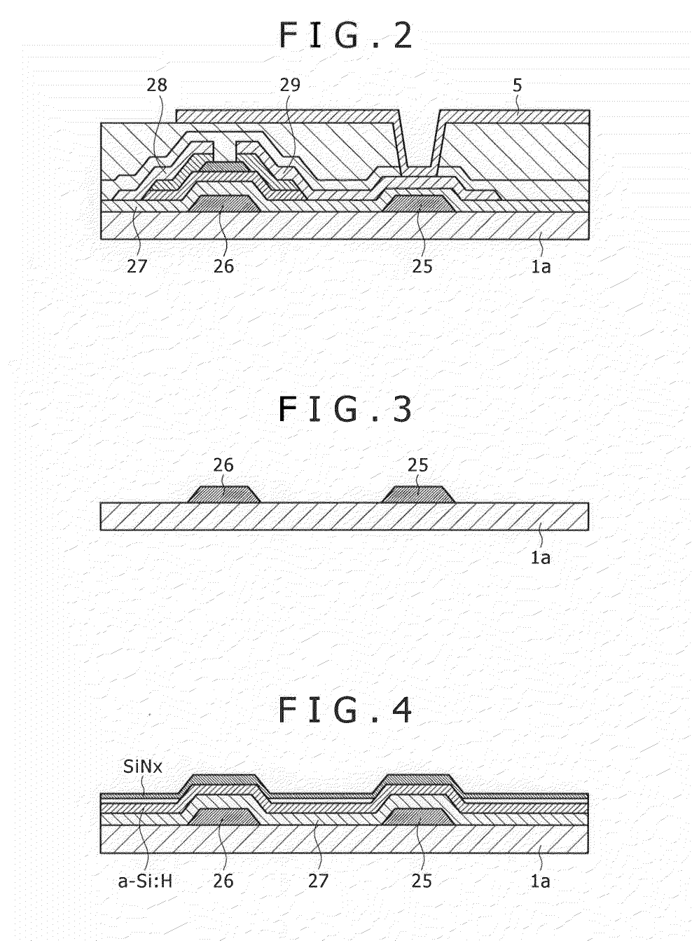

The following is a brief description of the method for producing the TFT array substrate shown in FIG. 2. Incidentally, the thin film transistor as the switching element is that of amorphous silicon in which the semiconductor layer is hydrogenated amorphous silicon.

The first step starts with sputtering to form an aluminum alloy film (about 200 nm thick) on the glass substrate 1a. Then the aluminum alloy film undergoes patterning by etching to form the gate electrode 26 and the scanning line 25, as shown in FIG. 3. Etching is carried out to make the edge of the aluminum alloy film slope with an angle of about 30-40° for complete coverage with the gate insulating film 27 (mentioned later). Plasma CVD is performed to form the gate insulating film 27 of silicon oxide (SiOₓ), about 300 nm thick, which is further covered with a hydrogenated amorphous silicon film (a-Si:H), about 50 nm thick, and a silicon nitride film (SiNₓ), about 300 nm thick.

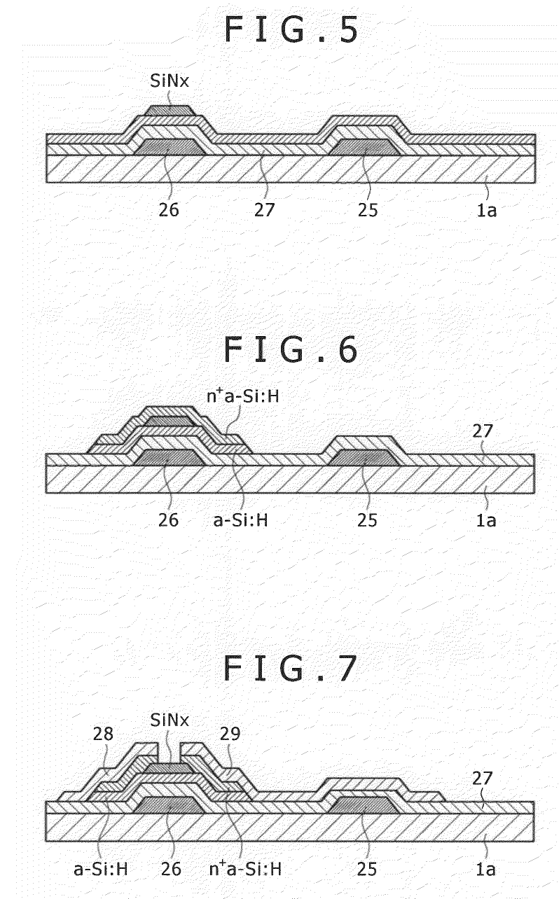

The silicon nitride film (SiNₓ) undergoes pattering by back exposure through the gate electrode 26 as a mask to form the channel protective film, as shown in FIG. 5. The entire surface is covered with an n⁺-type hydrogenated amorphous silicon film (n⁺a-Si:H) doped with phosphorus, about 50 nm thick. Both the hydrogenated amorphous silicon film (a-Si:H) and the n⁺-type hydrogenated amorphous silicon film (n⁺a-Si:H) undergo patterning as shown in FIG. 6.

The entire surface is covered with an aluminum alloy film, about 300 nm thick, which subsequently undergoes patterning to form the source electrode 28 (integral with the signal line) and the drain electrode 29 (in contact with the transparent conductive film 5), as shown in FIG. 7. The n⁺-type hydrogenated amorphous silicon film (n⁺a-Si:H) on the channel protective film (SiNₓ) are removed by using the source electrode 28 and the drain electrode 29 as the mask.

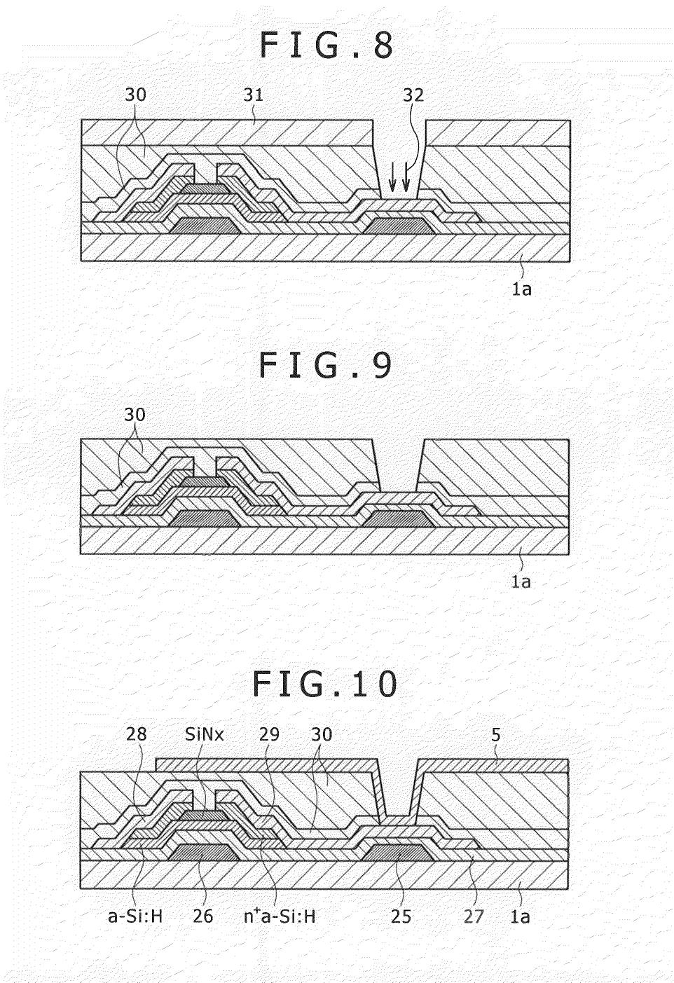

Plasma CVD is performed at about 260° C. to form the silicon nitride film 30, about 300 nm thick, which functions as the protective film, as shown in FIG. 8. The silicon nitride film 30 is covered with the photoresist film 31. Dry etching is performed for patterning to form the contact hole 32 in the silicon nitride film 30. At the same time, another contact hole (not shown) is formed for connection with TAB on the gate electrode at the panel end.

Ashing with oxygen plasma is performed and the photoresist layer 31 is removed by using an amine-type removing solution, as shown in FIG. 9. Within about 8 hours after the previous step, the ITO film (about 40 nm thick) is formed, which subsequently undergoes patterning to form the transparent conductive film 5, as shown in FIG. 10. At the same time, the ITO film is patterned for bonding with TAB at the connecting part of TAB of the gate electrode at the panel end. In this way the TFT array substrate is completed.

The above-mentioned steps pose a serious drawback. That is, when the ITO film for the transparent conductive film 5 is formed by sputtering on the aluminum alloy film for the drain electrode 29, an oxide film (AlOₓ) is formed between the ITO film and the aluminum alloy film and this oxide film results in an increased contact resistance. A known way to remedy this drawback is to form the ITO film (about 5-20 nm thick, preferably bout 10 nm thick) in an oxygen-free atmosphere while preventing the aluminum alloy film from surface oxidation in the initial film forming stage. It is also known that a stable, low contact resistance is achieved if the oxygen content in the AlOₓ is kept below 44 atom %.

The present inventors investigated differently from the foregoing to minimize contact resistance between the aluminum alloy film and the transparent conductive film 5. They found that the object is achieved if the surface of the aluminum alloy film (for the gate electrode and the source-drain electrodes) undergoes wet etching (with an alkaline solution) or dry etching (with a mixed gas of SF₆ and Ar) before it is brought into direct contact with the transparent conductive film. Such etching dissolves aluminum and causes alloying elements nobler than aluminum (which are contained in intermetallic compounds) to precipitate on the surface of the aluminum alloy film. The precipitates of alloying elements cause surface roughness on the surface of the aluminum alloy. When the surface roughness have a maximum roughness (Rz) of 5 nm, the contact resistance becomes minimal. This finding led to the present invention.

The electrode with its aluminum alloy film roughened as mentioned above hardly forms oxides (AlOₓ), which cause high contact resistance mentioned above, even when it comes into contact with the transparent conductive film. In some cases, precipitates containing metals nobler than aluminum come into direct contact with the transparent conductive film. This is the reason for the low contact resistance between the aluminum alloy film and the transparent conductive film.

To make surface roughness on the aluminum alloy film as mentioned above, it is necessary to perform wet etching (with an alkaline solution) or dry etching on the surface of the aluminum alloy film before the aluminum alloy film is brought into direct contact with the transparent conductive film. The amount (or depth) of etching should preferably be no less than 5 nm so that the resulting surface roughness has the maximum height roughness no smaller than 5 nm. This etching may be performed at any time before the aluminum alloy film is physically brought into direct contact with the transparent conductive film or before the interlayer insulating film of silicon nitride (SiNₓ) shown in FIG. 8 is formed.

The alkaline solution for wet etching includes, for example, an aqueous solution (pH 9-13) of resist remover (“TOK106” from TOKYO OHKA KOGYO CO., LTD.) or an aqueous solution of sodium hydroxide. It dissolves aluminum but does not dissolve metals nobler than aluminum.

The etching gas for dry etching includes, for example, a mixed gas of SF₆ (60%) and Ar (40%). This etching gas is different from a mixed gas of SF₆, Ar, and O₂, which is commonly used for dry etching of silicon nitride film. The latter mixed gas does not achieve the object of the present invention.

The foregoing etching with an alkaline solution or a mixed gas causes precipitates (containing metals nobler aluminum) to concentrate on the surface of the aluminum alloy film.

Metals nobler than aluminum denote those which have a smaller ionization tendency than aluminum. Such metals includes Ni, Co, Ag, Au, and Zn. One or more than one of them may be used. Their content should be about 0.1-1.0 atom % in the aluminum alloy film. A content less than 0.1 atom % is too small for them to form surface roughness as required, which leads to a rather high contact resistance. A content more than 1.0 atom % is detrimental, making the aluminum alloy film itself increase in electric resistance.

The aluminum alloy film in the present invention may also contain one or more than on species of rare earth elements in addition to the above-mentioned metals. The rare earth elements added in an amount of 0.1-0.5 atom % increase heat resistant (up to 300° C. and higher) and improve mechanical strength and corrosion resistance. They are selected from lanthanoids, particularly La, Gd, and Nd.

The TFT array substrate produced as mentioned above is used for a display device, such as a liquid crystal display unit. It has a minimal adverse effect on the display quality because contact resistance is kept very low between the transparent conductive film and the connection wiring.

The present invention will be described in more detail with reference to the following examples, which are not intended to restrict the scope thereof and may be properly modified or changed within the scope thereof.

### EXAMPLES

### Example 1

A non-alkali glass plate (0.7 mm thick) as a substrate was coated by sputtering with a thin film of aluminum alloy (varying in composition) which functions as the gate electrode and the source-drain electrodes. The aluminum alloy contains Al, Ni (0.2-1.0 atom %), and La (0.1-0.5 atom %). The thin film is about 300 nm thick. The coated glass plates were used as samples.

The samples were divided into four groups (A to D). The samples of Group A (designated as Test Nos. 1 to 3 in Table 1 given later) were left as such, and the samples of Group D (designated at Test Nos. 15 to 22 in Table 1) underwent wet etching with an alkaline solution (an aqueous solution, pH 9-13, of resist remover “TOK106” from TOKYO OHKA KOGYO CO., LTD.).

The aluminum alloy thin film, with or without etching (in both Group A and Group D), underwent photolithography and etching for patterning. This etching was performed such that the aluminum alloy thin film has its edge sloped about 30-40°. On the aluminum alloy thin film was formed a silicon nitride film (SiNₓ), 300 nm thick, by plasma CVD at 250° C. for about 6 minutes. The silicon nitride film underwent photolithography and dry etching to form a contact hole therein. (The contact hole has a contact area of 10×10 μm.) The dry etching was reactive ion etching (RIE) with a mixed gas of SF₆ (33.3%), O₂ (26.7%), and Ar (40%). This dry etching was followed by 100% overetching. Ashing with oxygen plasma was performed and then the photoresist was moved by using a remover. After standing for 8 hours, the aluminum alloy thin film was coated by sputtering with an ITO film, 200 nm thick.

The samples in Group B (designated as Test Nos. 4 to 11 in Table 1) underwent wet etching with an aqueous solution, pH 9-13, of resist remover “TOK106” from TOKYO OHKA KOGYO CO., LTD., and the samples in Group C (designated as Test Nos. 12 to 14 in Table 1) were left as such. After standing for 8 hours, the aluminum alloy thin film was coated by sputtering with an ITO film, 200 nm thick.

The samples in both Group A and Group D underwent photolithography and etching to make a patterned area (10×10 μm) for measurement of contact resistance.

The foregoing samples were examined for contact resistance between the ITO film (oxide transparent film) and the aluminum alloy film by four-terminal Kelvin method. Some of them (Test Nos. 1 and 10) were also examined for structure of interface between the aluminum alloy film and the ITO film under a transmission electron microscope (TEM).

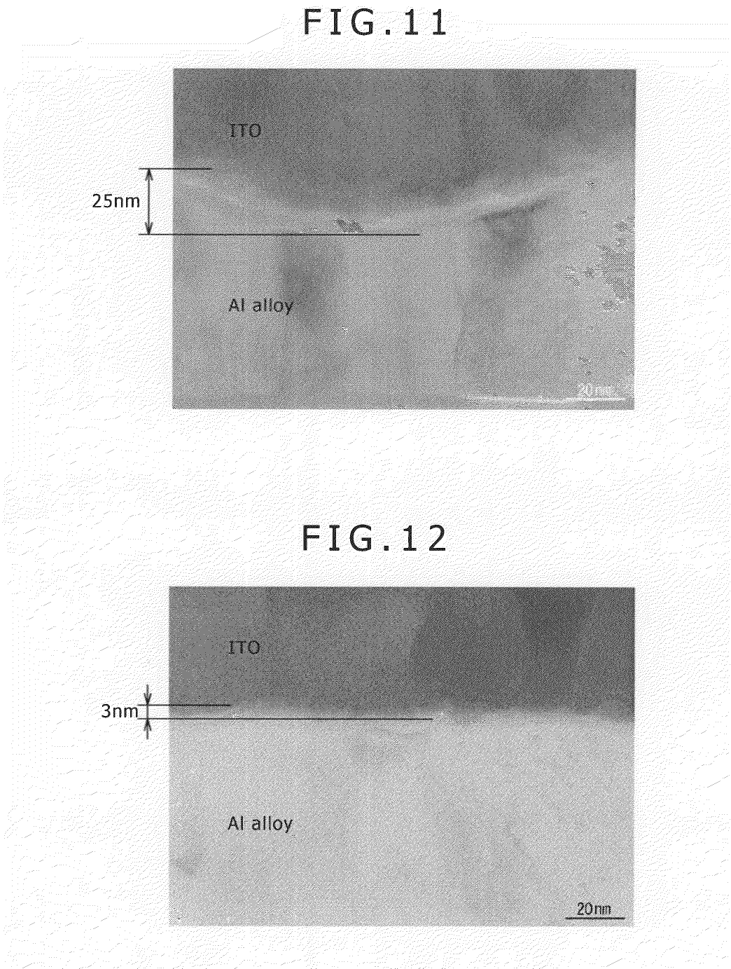

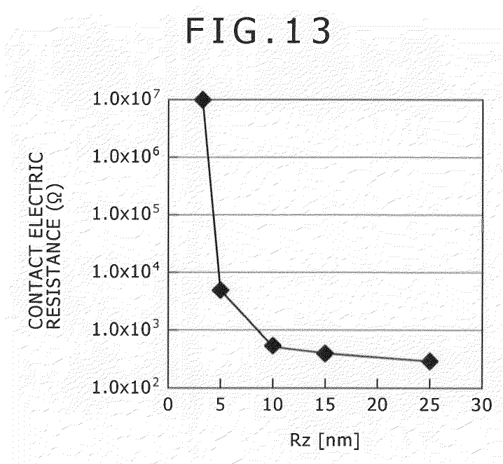

Table 1 below shows the results of measurement of contact resistance together with the amount of etching and the composition of the aluminum alloy (in terms of atom % of Ni/La). They were also examined for surface roughness at the interface between the transparent conductive film and the aluminum alloy thin film (in terms of maximum height Rz according to JIS B0601 (2001)). The results are shown in Table 1. FIGS. 11 and 12 are the electron micrographs (TEM) showing respectively the cross section of interface between the aluminum alloy film and the ITO film in Test No. 10 (according to the present invention) and Test No. 1 (for comparison).

TABLE 1

| | | | Composition of | | |
|---|---|---|---|---|---|
| | | Amount of | aluminum alloy | Contact | |
| Test No. | Group | wet etching (nm) | (Ni/La: atom %) | resistance (Ω) | Rz (nm) |
| 1 | A | — | 0.2/0.35 | 1.0 × 10⁶~1.0 × 10⁸ | 3 |
| 2 | A | — | 0.5/0.35 | 300~1.0 × 10³ | 3 |
| 3 | A | — | 1.0/0.35 | 200-500 | 4 |
| 4 | B | 15 | 0.2/0.35 | 350-700 | 10 |
| 5 | B | 15 | 0.2/0.1 | 400-800 | 12 |
| 6 | B | 15 | 0.2/0.5 | 300-800 | 9 |
| 7 | B | 15 | 0.5/0.35 | 90-350 | 10 |
| 8 | B | 15 | 1.0/0.35 | 70-250 | 12 |
| 9 | B | 5 | 0.2/0.35 | 1.0 × 10³~1.0 × 10⁴ | 5 |
| 10 | B | 25 | 0.2/0.35 | 250-550 | 15 |
| 11 | B | 45 | 0.2/0.35 | 200-500 | 25 |
| 12 | C | — | 0.2/0.35 | 2.0 × 10⁶~2.0 × 10⁸ | 3 |
| 13 | C | — | 0.5/0.35 | 350~1.2 × 10³ | 3 |
| 14 | C | — | 1.0/0.35 | 300-900 | 4 |
| 15 | D | 15 | 0.2/0.35 | 400-800 | 10 |
| 16 | D | 15 | 0.2/0.1 | 450-900 | 12 |
| 17 | D | 15 | 0.2/0.5 | 400-800 | 9 |
| 18 | D | 15 | 0.2/0.5 | 150-450 | 10 |
| 19 | D | 15 | 1.0/0.35 | 100-300 | 12 |
| 20 | D | 5 | 0.2/0.35 | 2.0 × 10³~2.0 × 10⁴ | 5 |
| 21 | D | 25 | 0.2/0.35 | 300-650 | 15 |
| 22 | D | 45 | 0.2/0.35 | 280-550 | 25 |

It is apparent from Table 1 that timely wet etching to form controlled minute irregularities on the surface of the aluminum alloy film results in an adequate contact resistance between the ITO film (as the oxide conductive film) and the Al—Ni—La alloy film (as the gate electrode or the source-drain electrodes).

It is apparent from the foregoing results that the larger the surface roughness Rz of the Al—Ni—La alloy film, the smaller the contact resistance. The effect of reducing contact resistance is significant when the surface roughness Rz is no smaller than 5 nm.

### Example 2

A non-alkali glass plate (0.7 mm thick) as a substrate was coated by sputtering with a thin film of aluminum alloy which functions as the gate electrode and the source-drain electrodes. The aluminum alloy contains Al and Ni (0.22 atom %). The thin film is about 300 nm thick. The coated glass plate was used as a sample.

The aluminum alloy thin film on the sample underwent wet etching with an aqueous solution, pH 9-13, of resist remover “TOK106” from TOKYO OHKA KOGYO CO., LTD. Duration of wet etching was varied so as to control the amount of etching. The thus treated samples were examined for contact resistance in the same way as in Example 1. They were also examined for surface roughness at interface between the transparent conductive film and the aluminum alloy thin film (in terms of maximum height Rz according to JIS B0601 (2001)). The results are shown in Table 2. (The symbol “-” means no data available.) The data in Table 2 are graphed in FIG. 13 to represent the relation between the height (Rz) of roughness of the aluminum alloy film and the contact resistance.

TABLE 2

| | Duration | Amount | Surface | |
|---|---|---|---|---|
| | of wet | of wet | roughness Rz | Contact |
| Test | etching | etching | of aluminum | resistance |
| No. | (min) | (nm) | alloy thin film (nm) | (Ω) |
| 23 | 0 | 0 | 3 | 1.0 × 10⁷ |
| 24 | 5 | 5 | 5 | 5.0 × 10³ |
| 25 | 10 | 10 | — | 7.0 × 10² |
| 26 | 15 | 15 | 10 | 5.3 × 10² |
| 27 | 20 | 20 | — | 4.3 × 10² |
| 28 | 25 | 25 | 15 | 4.0 × 10² |
| 29 | 45 | 45 | 25 | 3.0 × 10² |

It is apparent from the foregoing results that the larger the amount of wet etching (and hence the larger the surface roughness Rz of the aluminum alloy thin film), the smaller the contact resistance. The effect of reducing contact resistance is significant when the amount of wet etching is no smaller than 5 nm and the surface roughness Rz is no smaller than 5 nm.

### Example 3

A non-alkali glass plate (0.7 mm thick) as a substrate was coated by sputtering with a thin film of aluminum alloy which functions as the gate electrode and the source-drain electrodes. The aluminum alloy contains Al, Ni (0.3 atom %), and La (0.35 atom %). The thin film is about 300 nm thick. The coated glass plate was used as a sample.

Each sample was processed in the same way as in Example 1 to form a contact hole (with an area of 10×10 μm) in the silicon nitride film and then underwent dry etching with a mixed gas composed of SF₆ (33.3%), O₂ (26.7%), and Ar (40%) or a mixed gas composed of SF₆ (60%) and Ar (40%). The dry etching was reactive ion etching (RIE). It also varied in duration from level 1 to level 3 as defined below. After standing for 8 hours, the surface of the aluminum alloy thin film was coated by sputtering with an ITO film, 200 nm thick.

Etching level 1: twice the duration necessary to remove the silicon nitride film formed on the aluminum alloy film.
Etching level 2: three times the duration necessary to remove the silicon nitride film formed on the aluminum alloy film.
Etching level 3: four times the duration necessary to remove the silicon nitride film formed on the aluminum alloy film.

The samples thus prepared were examined for contact resistance in the same way as in Example 1. The results are shown in Table 3 below. It is noted that dry etching with a specific mixed gas reduces contact resistance.

TABLE 3

| | | | Etch- | Contact |
|---|---|---|---|---|
| Test | Composition of | | ing | resistance |
| NO. | aluminum alloy | Etching gas (%) | level | (Ω) |
| 30 | Al—0.3Ni—0.35La | SF₆:33.3, O₂:26.7, Ar:40 | 1 | 1.1 × 10⁸ |
| 31 | Al—0.3Ni—0.35La | SF₆:33.3, O₂:26.7, Ar:40 | 2 | 3.1 × 10⁸ |
| 32 | Al—0.3Ni—0.35La | SF₆:33.3, O₂:26.7, Ar:40 | 3 | 3.3 × 10⁸ |
| 33 | Al—0.3Ni—0.35La | SF₆:60, Ar:40 | 1 | 2.8 × 10⁸ |
| 34 | Al—0.3Ni—0.35La | SF₆:60, Ar:40 | 3 | 5.4 × 10² |

### Example 4

A non-alkali glass plate (0.7 mm thick) as a substrate was coated by sputtering with a thin film of aluminum alloy which functions as the gate electrode and the source-drain electrodes. The aluminum alloy contains Al, Ag (0.2 to 1.0 atom %), and La (0.1 to 0.5 atom %). The thin film is about 300 nm thick. The coated glass plate was used as a sample.

The samples were divided into four groups (E to H). The samples of Group E (designated as Test Nos. 35 to 37 in Table 4 given later) were left as such, and the samples of Group H (designated at Test Nos. 49 to 56 in Table 4) underwent wet etching with an alkaline solution (an aqueous solution, pH 9-13, of resist remover “TOK106” from TOKYO OHKA KOGYO CO., LTD.).

The aluminum alloy thin film, with or without etching (in both Group E and Group H), underwent photolithography and etching for patterning. This etching was performed such that the aluminum alloy thin film has its edge sloped about 30-40°. On the aluminum alloy thin film was formed a silicon nitride film (SiNₓ), 300 nm thick, by plasma CVD at 250° C. for about 6 minutes. The silicon nitride film underwent photolithography and dry etching to form a contact hole therein. (The contact hole has a contact area of 10×10 μm.) The dry etching was reactive ion etching (RIE) with a mixed gas of SF₆ (33.3%), O₂ (26.7%), and Ar (40%). This dry etching was followed by 100% overetching. Ashing with oxygen plasma was performed and then the photoresist was moved by using a remover. After standing for 8 hours, the aluminum alloy thin film was coated by sputtering with an ITO film, 200 nm thick.

The samples in Group F (designated as Test Nos. 38 to 45 in Table 4) underwent wet etching with an aqueous solution, pH 9-13, of resist remover “TOK106” from TOKYO OHKA KOGYO CO., LTD., and the samples in Group G (designated as Test Nos. 46 to 48 in Table 4) were left as such. After standing for 8 hours, the aluminum alloy thin film was coated by sputtering with an ITO film, 200 nm thick.

The samples in both Group F and Group G underwent photolithography and etching to make a patterned area (10×10 μm) for measurement of contact resistance.

The foregoing samples were examined for contact resistance between the ITO film (oxide transparent film) and the aluminum alloy film by four-terminal Kelvin method. Some of them (Test Nos. 35 and 44) were also examined for structure of interface between the aluminum alloy film and the ITO film under a transmission electron microscope (TEM).

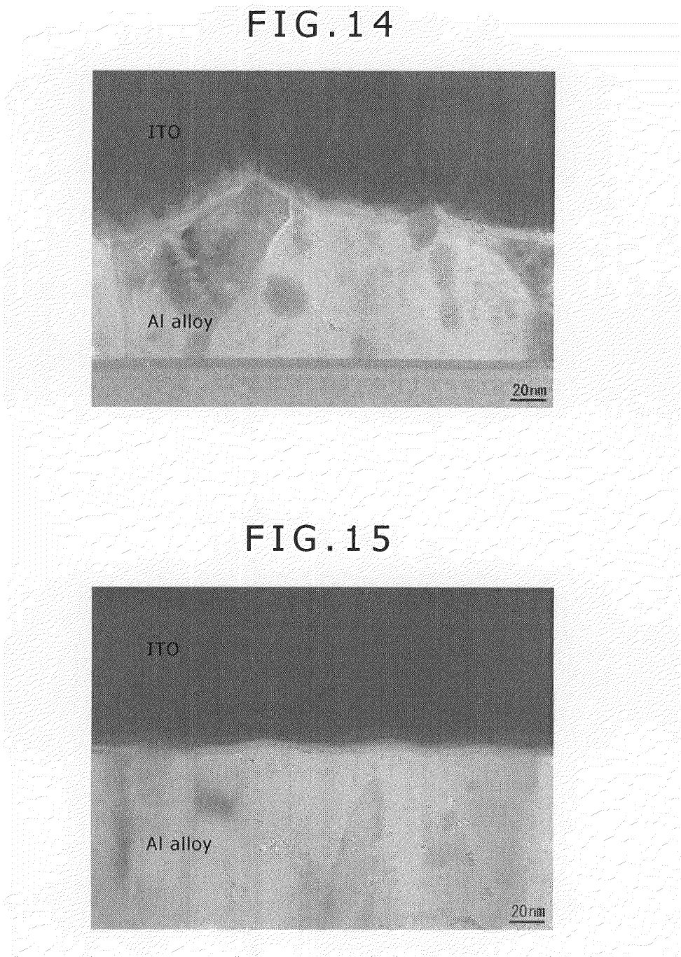

Table 4 below shows the results of measurement of contact resistance together with the amount of etching and the composition of the aluminum alloy (in terms of atom % of Ag/La). They were also examined for surface roughness at the interface between the transparent conductive film and the aluminum alloy thin film (in terms of maximum height Rz according to JIS B0601 (2001)). The results are shown in Table 4. FIGS. 14 and 15 are TEM photographs showing respectively the cross section of interface between the aluminum alloy film and the ITO film in Test No. 44 (according to the present invention) and Test No. 35 (for comparison).

TABLE 4

| | | | Composition of | | |
|---|---|---|---|---|---|
| | | Amount of | aluminum alloy | Contact | |
| Test No. | Group | wet etching (nm) | (Ag/La: atom %) | resistance (Ω) | Rz (nm) |
| 35 | E | — | 0.2/0.35 | 1.0 × 10⁷-1.0 × 10⁹ | 4 |
| 36 | E | — | 0.5/0.35 | 1.0 × 10⁷-1.0 × 10⁹ | 4 |
| 37 | E | — | 1.0/0.35 | 1.0 × 10⁶-5.0 × 10⁸ | 5 |
| 38 | F | 15 | 0.2/0.35 | 100-350 | 13 |
| 39 | F | 15 | 0.2/0.1 | 120-350 | 16 |
| 40 | F | 15 | 0.2/0.5 | 90-300 | 12 |
| 41 | F | 15 | 0.5/0.35 | 20-250 | 13 |
| 42 | F | 15 | 1.0/0.35 | 20-200 | 16 |
| 43 | F | 5 | 0.2/0.35 | 500-1.0 × 10⁴ | 7 |
| 44 | F | 25 | 0.2/0.35 | 80-350 | 20 |
| 45 | F | 45 | 0.2/0.35 | 70-380 | 33 |
| 46 | G | — | 0.2/0.35 | 2.0 × 10⁷-2.0 × 10⁹ | 4 |
| 47 | G | — | 0.5/0.35 | 2.0 × 10⁷-2.0 × 10⁹ | 4 |
| 48 | G | — | 1.0/0.35 | 2.0 × 10⁶-2.0 × 10⁸ | 5 |
| 49 | H | 15 | 0.2/0.35 | 150-450 | 13 |
| 50 | H | 15 | 0.2/0.1 | 180-450 | 16 |
| 51 | H | 15 | 0.2/0.5 | 100-380 | 12 |
| 52 | H | 15 | 0.2/0.5 | 50-280 | 13 |
| 53 | H | 15 | 1.0/0.35 | 20-250 | 16 |
| 54 | H | 5 | 0.2/0.35 | 700-2.0 × 10⁴ | 7 |
| 55 | H | 25 | 0.2/0.35 | 100-400 | 20 |
| 56 | H | 45 | 0.2/0.35 | 80-420 | 33 |

It is apparent from Table 4 that timely wet etching to form controlled minute irregularities on the surface of the aluminum alloy film results in an adequate contact resistance between the ITO film (as the oxide conductive film) and the Al—Ag—La alloy film (as the gate electrode or the source-drain electrodes).

It is apparent from the foregoing results that the larger the surface roughness Rz of the Al—Ag—La alloy film, the smaller the contact resistance. The effect of reducing contact resistance is significant when the surface roughness Rz is no smaller than 5 nm.

The foregoing examples demonstrate that the present invention produces its effect when the aluminum alloy film is formed from Al—Ni—La alloy or Al—Ag—La alloy; however, it was confirmed that the same effect is produced even when the second alloying element (Ni or Ag as a metal nobler than aluminum) is replaced by Co, Au, or Zn, and the third alloy element (La) is replaced by Gd or Nd as a rare earth element.

What is claimed is:

1. An electrode of low contact resistance type which is an aluminum alloy film in direct contact with a transparent oxide electrode, wherein said aluminum alloy film contains 0.1-1.0 atom % of metal nobler than aluminum and is in direct contact with a transparent oxide electrode through a surface having surface roughness no smaller than 5 nm in terms of maximum height Rz.

2. The electrode of low contact resistance type as defined in claim 1, wherein the metal nobler than aluminum is at least one species selected from the group consisting of Ni, Co, Ag, Au, and Zn, and the surface roughness is formed as an intermetallic compound containing such metals precipitates on the surface of the aluminum alloy film.

3. The electrode of low contact resistance type as defined in claim 2, wherein the aluminum alloy film contains 0.1-0.5 atom % of at least one species of rare earth elements.

4. The electrode of low contact resistance type as defined in claim 1, which is suitable for use as the gate electrode.

5. The electrode of low contact resistance type as defined in claim 1, which is suitable for use as the source-drain electrodes.

6. A display unit which is provided with the electrode of low contact resistance type as defined in claim 1.

7. A display unit which is provided with the electrode of low contact resistance type as defined in claim 2.

8. A display unit which is provided with the electrode of low contact resistance type as defined in claim 3.

9. A display unit which is provided with the electrode of low contact resistance type as defined in claim 4.

10. A display unit which is provided with the electrode of low contact resistance type as defined in claim 5.

11. A method for producing the electrode of low contact resistance type as defined in claim 1 which comprises etching the surface of the aluminum alloy film with an alkaline solution, thereby forming the surface roughness, before it is brought into direct contact with the transparent oxide conductive film.

12. The method as defined in claim 11, wherein etching is carried out such that the etching depth is no smaller than 5 nm.

13. A method for producing the electrode of low contact resistance type as defined in claim 1 which comprises dry-etching the surface of the aluminum alloy film with a mixed gas of SF₆ and Ar, thereby forming the surface roughness, before it is brought into direct contact with the transparent oxide conductive film.
